(19) United States
(12) Patent Application Publication
(10) Pub. No.: US 2025/0089270 A1
(43) Pub. Date: Mar. 13, 2025

(54) MEMORY DEVICE, MANUFACTURING METHOD THEREOF, AND ELECTRONIC APPARATUS INCLUDING MEMORY DEVICE

(71) Applicant: Samsung Electronics Co., Ltd., Suwon-si (KR)

(72) Inventors: Kiyeon YANG, Suwon-si (KR); Haeryong KIM, Suwon-si (KR); Hajun SUNG, Suwon-si (KR); Changseung LEE, Suwon-si (KR)

(73) Assignee: Samsung Electronics Co., Ltd., Suwon-si (KR)

(21) Appl. No.: 18/540,222

(22) Filed: Dec. 14, 2023

(30) Foreign Application Priority Data
Sep. 11, 2023 (KR) 10-2023-0120487

(51) Int. Cl. H10B 63/00; H10B 63/10

(52) U.S. Cl. CPC H10B 63/845; H10B 63/10

(57) ABSTRACT

Provided are a memory device, a manufacturing method thereof, and an electronic apparatus including the memory device. The memory device may include a plurality of first conductors arranged apart from each other and perpendicular to a substrate, a second conductor extending perpendicular to the substrate, a chalcogenide layer extending perpendicular to the substrate between the plurality of first conductors and the second conductor, and a plurality of first diffusion barrier layers selectively arranged only on the plurality of first conductors between the plurality of first conductors and the chalcogenide layer. The plurality of first diffusion barrier layers each may include a carbon-based material.

### CROSS-REFERENCE TO RELATED APPLICATION

This application claims the benefit of Korean Patent Application No. 10-2023-0120487, filed on Sep. 11, 2023 in the Korean Intellectual Property Office, the disclosure of which is incorporated herein in its entirety by reference.

### BACKGROUND

### 1. Field

The disclosure relates to a memory device, a manufacturing method thereof, and/or an electronic apparatus including the memory device.

### 2. Description of the Related Art

A chalcogenide material having phase change or threshold switching characteristics may be applied to a non-volatile memory device. The chalcogenide material may have various functions through a combination of constituent elements. In accordance with the recent trend toward lightness, thinness, and miniaturization of electronic products, there is a demand for highly integrated non-volatile memory devices using chalcogenide materials.

### SUMMARY

Provided are a memory device, a manufacturing method thereof, and/or an electronic apparatus including the memory device.

Additional aspects will be set forth in part in the description which follows and, in part, will be apparent from the description, or may be learned by practice of the presented embodiments.

According to an embodiment of the disclosure, a memory device may include a plurality of first conductors arranged apart from each other and perpendicular to a substrate, a second conductor extending perpendicular to the substrate, a chalcogenide layer extending perpendicular to the substrate between the plurality of first conductors and the second conductor, and a plurality of first diffusion barrier layers selectively arranged only on the plurality of first conductors between the plurality of first conductors and the chalcogenide layer. The plurality of first diffusion barrier layers each may include a carbon-based material.

In some embodiments, each of the plurality of first conductors may extend parallel to the substrate, and the plurality of first diffusion barrier layers may be on side surfaces of the plurality of first conductors.

In some embodiments, each of the plurality of first diffusion barrier layers may include carbon, a carbon nitride, or a compound of carbon and chalcogenide.

In some embodiments, the plurality of first conductors and the second conductor each may include a metal material.

In some embodiments, the chalcogenide layer may include at least one of a chalcogen element, Ge, As, and Sb.

In some embodiments, the chalcogenide layer may include a GeAsSe-based material, a GeSbTe-based material, a GeAsS-based material, a GeSbSe-based material, a GeAsTe-based material, or a GeSbS-based material.

In some embodiments, the memory device may further include a second diffusion barrier layer between the chalcogenide layer and the second conductor. The second diffusion barrier layer may include a carbon-based material.

In some embodiments, the second diffusion barrier layer may extend perpendicular to the substrate.

In some embodiments, the memory device may further include a plurality of insulating layers between the plurality of first conductors.

According to an embodiment of the disclosure, an electronic apparatus may include the memory device described above.

According to an embodiment of the disclosure, a method of manufacturing a memory device may include alternately stacking a plurality of first conductors and a plurality of insulating layers above a substrate, forming a through-hole penetrating the plurality of first conductors and the plurality of interlayer insulating layers in a direction perpendicular to the substrate, selectively depositing a plurality of first diffusion barrier layers only on side surfaces of the plurality of first conductors exposed through the through-hole, forming a chalcogenide layer on an inner wall of the through-hole, and forming a second conductor on the chalcogenide layer. The plurality of first diffusion barrier layers each may include a carbon-based material.

In some embodiments, each the plurality of first diffusion barrier layers may include carbon, a carbon nitride, or a compound of carbon and chalcogenide.

In some embodiments, the plurality of first conductors and the second conductor each may include a metal material.

In some embodiments, the chalcogenide layer may include at least one of a chalcogen element, Ge, As, and Sb.

In some embodiments, the chalcogenide layer may include a GeAsSe-based material, a GeSbTe-based material, a GeAsS-based material, a GeSbSe-based material, a GeAsTe-based material, or a GeSbS-based material.

In some embodiments, the selectively depositing the plurality of first diffusion barrier layers may include selectively adsorbing a precursor including carbon only on the side surfaces of the plurality of first conductors, and forming the plurality of first diffusion barrier layers by reacting the precursor adsorbed on the side surfaces of the plurality of first conductors with a reactive agent.

In some embodiments, the precursor may include a benzene-based, cyclopentadien-based, or aniline-based material.

In some embodiments, each of the chalcogenide layer and the second conductor may be formed to extend perpendicular to the substrate.

In some embodiments, the method may further include forming a second diffusion barrier layer including a carbon-based material between the chalcogenide layer and the second conductor.

In some embodiments, the second diffusion barrier layer may be formed to extend perpendicular to the substrate.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of a memory device according to an embodiment;

FIG. 2 is an enlarged view of a region A of FIG. 1;

FIG. 3 is a cross-sectional view of a memory device according to a comparative example;

FIGS. 4A to 4D are views for explaining a method of manufacturing a memory device, according to an embodiment;

FIGS. 4E to 4I are views for explaining a method of manufacturing a memory device, according to an embodiment;

FIGS. 5A to 5C are views showing a process of a diffusion barrier layer being selectively deposited on first conductors in a method of manufacturing a memory device, according to an embodiment;

FIG. 6 is a conceptual block diagram schematically showing an example of a device architecture applicable to an electronic apparatus, according to an embodiment;

FIG. 7 is a block diagram of a memory system according to an embodiment; and

FIG. 8 is a block diagram of a neuromorphic apparatus according to an embodiment and an external device connected thereto.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, embodiments are described in detail with reference to the accompanying drawings. Throughout the drawings, like reference numerals denote like elements, and sizes of components in the drawings may be exaggerated for convenience of explanation and clarity. As embodiments described below are examples, other modifications may be produced from the embodiments.

When a constituent element is disposed “above” or “on” to another constituent element, the constituent element may include not only an element directly contacting on the upper/lower/left/right sides of the other constituent element, but also an element disposed above/under/left/right the other constituent element in a non-contact manner. As used herein, the singular forms “a,” “an,” and “the” are intended to include the plural forms as well, unless the context clearly indicates otherwise. It will be further understood that the terms “comprises” and/or “comprising” used herein specify the presence of stated features or components, but do not preclude the presence or addition of one or more other features or components.

The use of the terms “a,” “an,” “the,” and similar referents in the context of describing the disclosure to be construed to cover both the singular and the plural. Also, the steps of all methods described herein can be performed in any suitable order unless otherwise indicated herein or otherwise clearly contradicted by context. The disclosure is not limited to the described order of the steps.

Furthermore, terms such as . . . portion,” “ . . . unit,” “ . . . module,” and “ . . . block” stated in the specification may signify a unit to process at least one function or operation and the unit may be embodied by hardware, software, or a combination of hardware and software.

Furthermore, the connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language provided herein, is intended merely to better illuminate the disclosure and does not pose a limitation on the scope of the disclosure unless otherwise claimed.

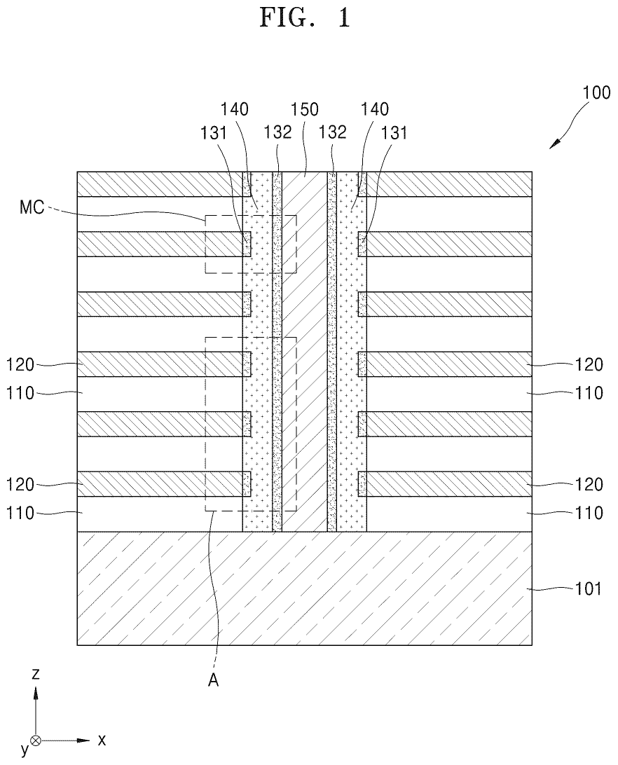

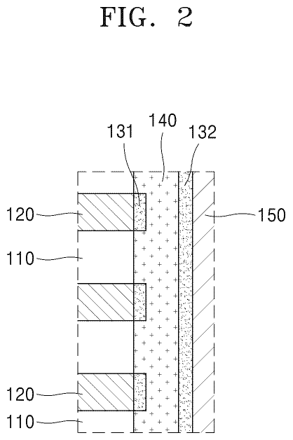

FIG. 1 is a cross-sectional view of a memory device 100 according to an embodiment. In FIG. 1, a vertical non-volatile memory device is illustrated, in which a plurality of memory cells MC are vertically stacked on a substrate 101. FIG. 2 is an enlarged view of a region A of FIG. 1.

Referring to FIGS. 1 and 2, the memory device 100 may include a plurality of cell strings disposed on the substrate 101, and each cell string is arranged to extend in a direction perpendicular to the substrate 101. In FIG. 1, for convenience, a cross-section of one cell string is illustrated as an example. The memory device 100 may include the memory cells MC vertically stacked on the substrate 101. Each of the memory cells MC may include one of a plurality of first conductors 120, one of a plurality of first diffusion barrier layers 131, a chalcogenide layer 140, a second diffusion barrier layer 132, and a second conductor 150, which are described below.

The substrate 101 may include one or more various materials. For example, the substrate 101 may include a semiconductor material, such as silicon (Si), germanium (Ge), silicon germanium (SiGe), silicon carbide (SiC), gallium arsenic (GaAs), indium arsenic (InAs), indium phosphide (InP), or the like, or include an insulating material, such as a silicon oxide, a silicon nitride, a silicon oxynitride, or the like.

The substrate 101 may further include a driving circuit area (not shown). The driving circuit area may include one or more transistors and a wiring structure electrically connected to the transistors. The transistor may include a gate, a gate insulating film, and a source/drain. The wiring structure may be arranged in an appropriate number and at an appropriate position according to the layout of the driving circuit area, the type and arrangement of a gate, and the like. The wiring structure may have a multilayer structure of two or more layers. In detail, the wiring structure may include a contact and a wiring layer electrically connected to each other, which may be sequentially stacked on the substrate 101. The contact and the wiring layer may each independently include metal, conductive metal nitride, metal silicide, or a combination thereof, and may include a conductive material, such as tungsten, molybdenum, titanium, cobalt, tantalum, nickel, tungsten silicide, titanium silicide, cobalt silicide, tantalum silicide, nickel silicide, and the like.

The wiring structure may include an interlayer insulating film that electrically separates respective elements. The interlayer insulating film may be arranged between a plurality of transistors, between a plurality of wiring layers, and/or between a plurality of contacts. The interlayer insulating film may include a silicon oxide, a silicon oxynitride, a silicon oxynitride, and the like.

The first conductors 120 and a plurality of insulating layers 110 are alternately stacked above the substrate 101 in the direction (z-axis direction) perpendicular to the substrate 101. Accordingly, the first conductors 120 are arranged apart from each other and perpendicular to the substrate 101, and each of the first conductors 120 extends parallel to the substrate 101.

A word line may be electrically connected to each of the first conductors 120. The first conductors 120 may each include a metal material having excellent electrical conductivity. For example, the first conductors 120 may each include TiN, Au, or the like, but the disclosure is not limited thereto. The insulating layers 110 are for insulating between the first conductors 120 adjacent to each other, and may each include, for example, a silicon oxide, a silicon nitride, and the like. However, the disclosure is not limited thereto.

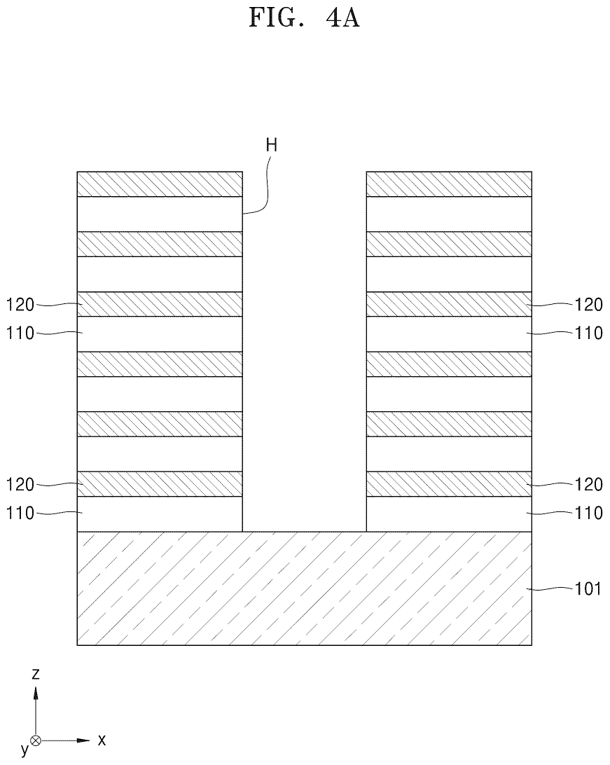

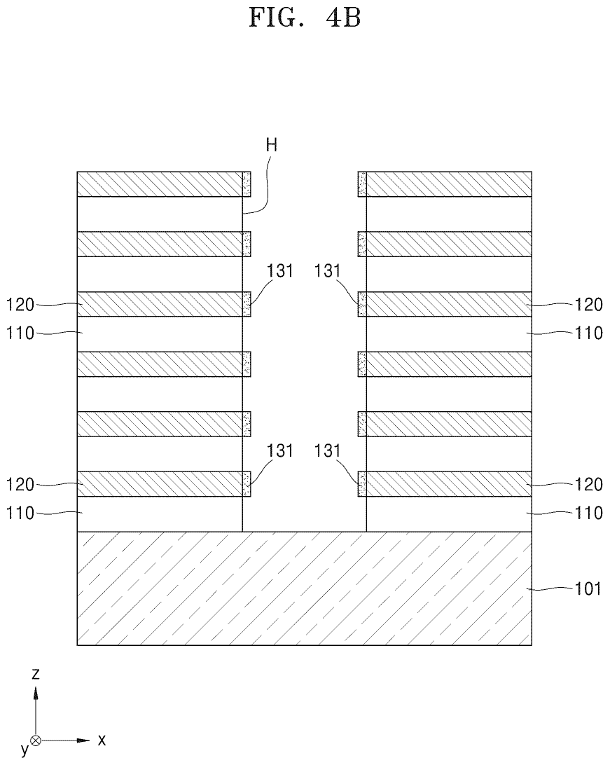

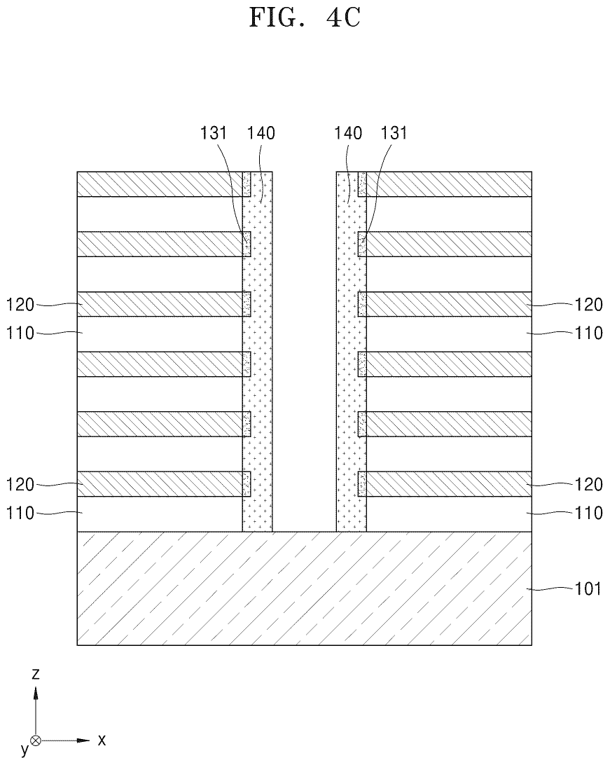

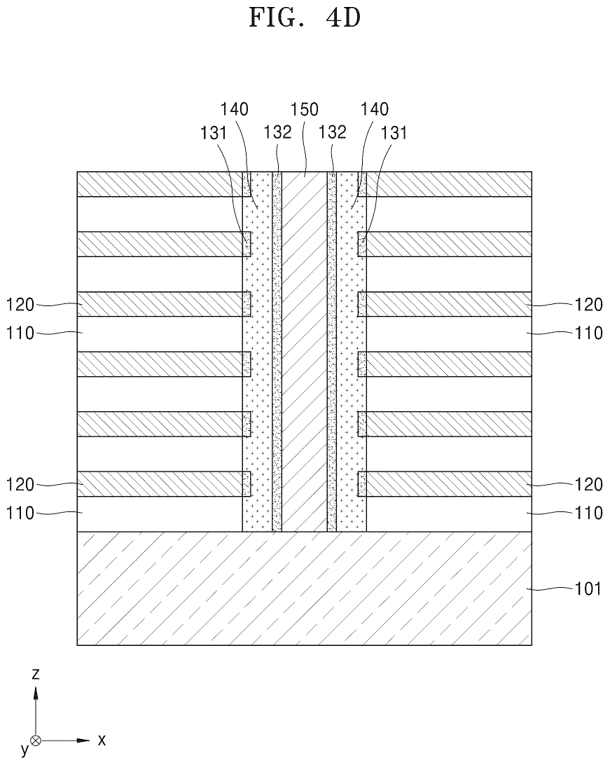

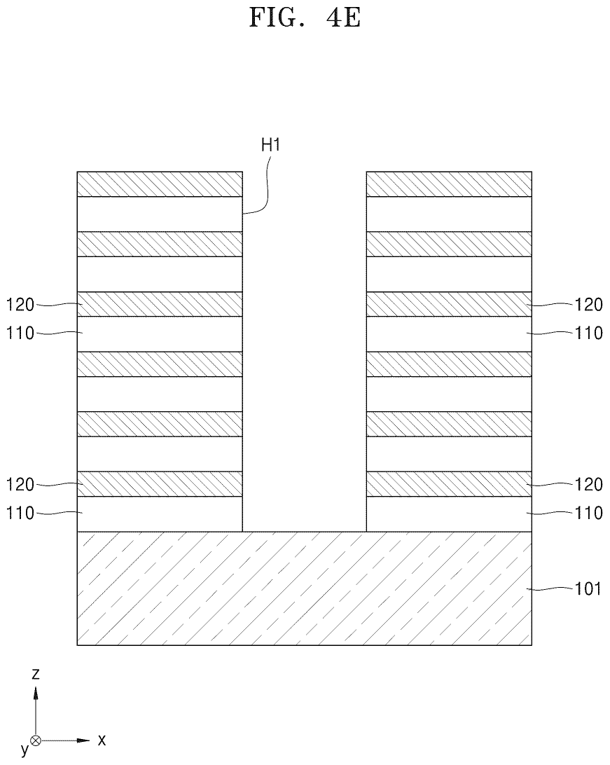

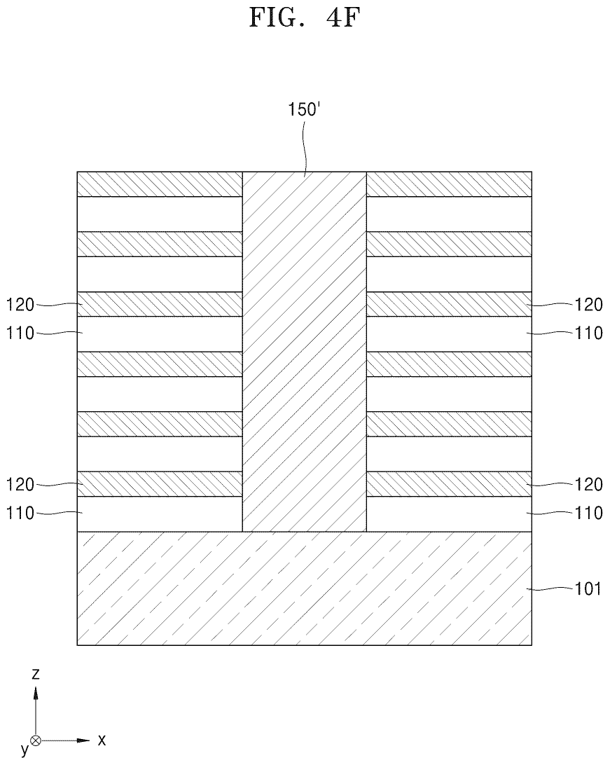

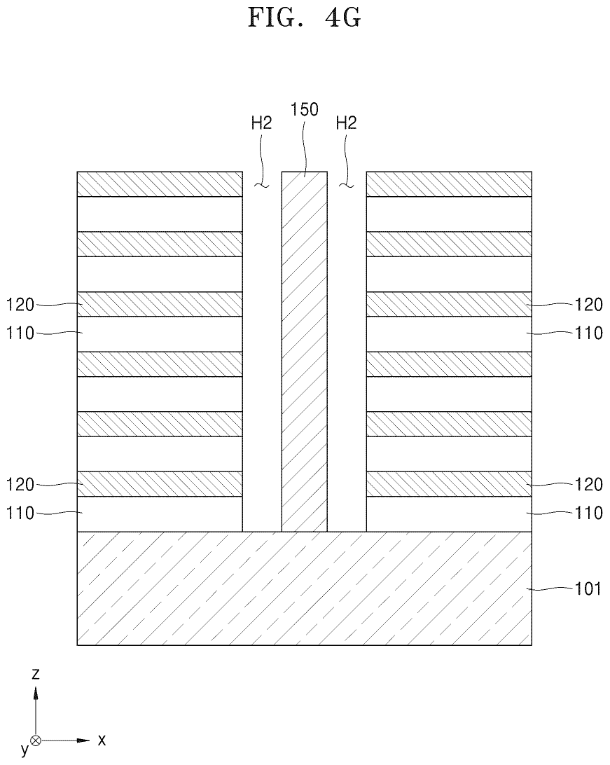

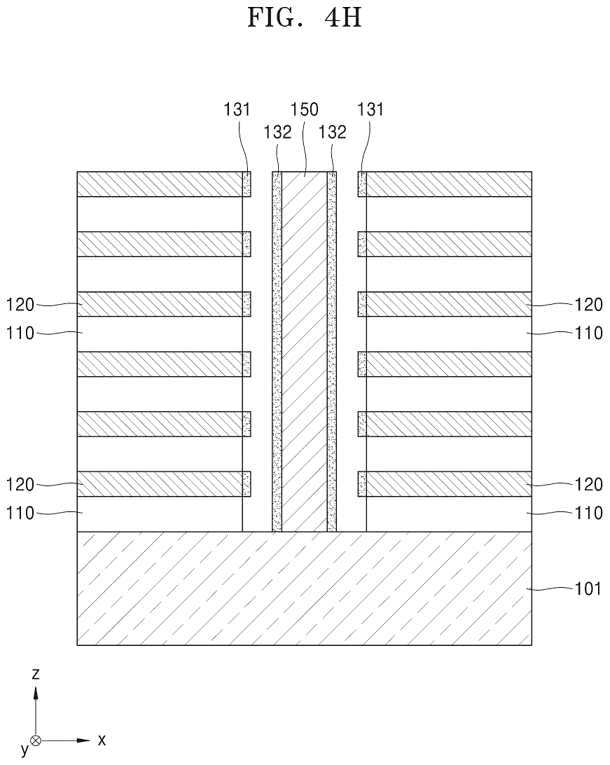

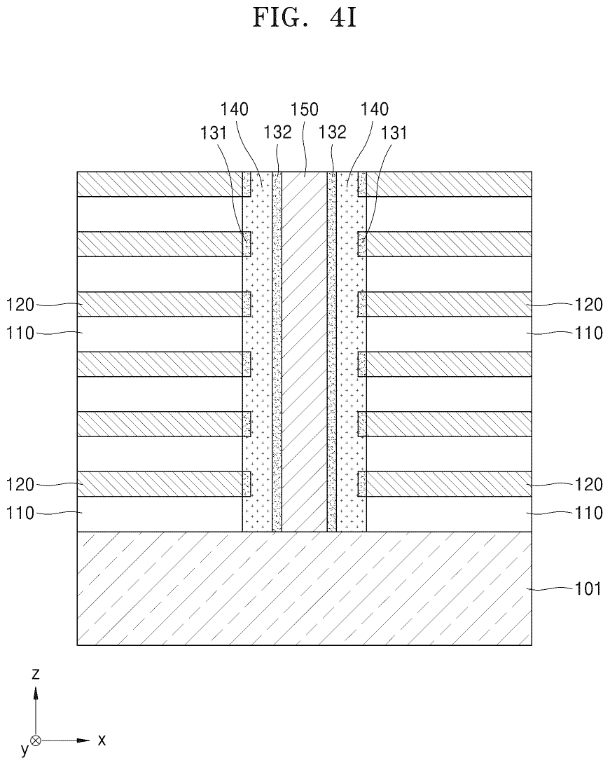

A through-hole H of FIG. 4B is formed in the first conductors 120 and the insulating layers 110 in the direction (z-axis direction) perpendicular to the substrate 101. The through-hole H may be formed to have, for example, a circular cross-section. The first diffusion barrier layers 131, the chalcogenide layer 140, the second diffusion barrier layer 132, and the second conductor 150 may be sequentially arranged in the inner wall of the through-hole H.

The chalcogenide layer 140 is arranged to cover the first diffusion barrier layers 131 in the inner wall of the through-hole H. The chalcogenide layer 140 may be formed in a cylindrical shape surrounding the second diffusion barrier layer 132 and the second conductor 150. The chalcogenide layer 140 is arranged to extend in the direction perpendicular to the substrate 101.

The chalcogenide layer 140 may include a chalcogenide material having non-volatile memory characteristics. The chalcogenide layer 140 may include at least one of a chalcogen element, Ge, As, and Sb. The chalcogen element may include at least one of Se, Te, and S. For example, the chalcogenide layer 140 may include a GeAsSe-based material, a GeSbTe-based material, a GeAsS-based material, a GeSbSe-based material, a GeAsTe-based material, or a GeSbS-based material.

The chalcogenide layer 140 may include a material (e.g., a GeAsSe-based material) having threshold switching characteristics. In this case, the chalcogenide layer 140 may exhibit non-volatile memory characteristics by changing a threshold switching voltage through a negative bias in an amorphous state of a chalcogenide material.

The chalcogenide layer 140 may include a material (e.g., GeSbTe) having phase change characteristics. In this case, as a resistance difference is generated by changing a chalcogenide material to a crystalline or amorphous structure through joule heat, the chalcogenide layer 140 may exhibit non-volatile memory characteristics. The chalcogenide layer 140 may further include a material (e.g., a GeAsSe-based material) having Ovonic threshold switching (OTS) characteristics.

The first diffusion barrier layers 131 are selectively arranged only on the first conductors 120 between the first conductors 120 and the chalcogenide layer 140. Each of the first diffusion barrier layers 131 is arranged on the side surface of each of the first conductors 120. In detail, each of the first diffusion barrier layers 131 is arranged on the inner surface of each of the first conductors 120 exposed through the through-hole H. The inner surface of each of the first conductors 120 extends parallel to the direction (z-axis direction) perpendicular to the substrate 101. Each of the first diffusion barrier layers 131 may be formed in a shape surrounding the second conductor 150. As described below, the first diffusion barrier layers 131 may be selectively formed only on the side surfaces of the first conductors 120 through area selective deposition (ASD).

The first diffusion barrier layers 131 may limit and/or prevent the mixing of the metal material of the first conductors 120 and the chalcogenide material of the chalcogenide layer 140. When the first conductors 120 including a metal material and the chalcogenide layer 140 including a chalcogenide material are brought into direct contact with each other, mixing between the metal material and the chalcogenide material occurs so that the memory device characteristics may deteriorate. In the present embodiment, as the first diffusion barrier layers 131 are arranged between the first conductors 120 and the chalcogenide layer 140, the mixing between the metal material and the chalcogenide material may be limited and/or prevented.

The first diffusion barrier layers 131 may each include a carbon-based material. For example, the first diffusion barrier layers 131 may each include a carbon layer. The first diffusion barrier layers 131 may each include a carbon nitride layer. The carbon nitride layer may be formed as carbon reacts with a reactive agent (e.g., a NH₃ gas) in the ASD process described below. The first diffusion barrier layers 131 may each include a compound layer of carbon and chalcogenide in which carbon and a chalcogenide material are mixed. As such, as the first diffusion barrier layers 131 are selectively arranged only on the first conductors 120, the generation of crosstalk between the memory cells MC may be limited and/or prevented.

The second conductor 150 is arranged inside the chalcogenide layer 140. In detail, the second conductor 150 may be arranged to fill the through-hole H in the chalcogenide layer 140. The second conductor 150 may be arranged to extend perpendicular to the substrate 101. The second conductor 150 may be formed in a cylindrical shape, and in this case, a filling insulating layer (not shown) may be arranged in the through-hole H inside the second conductor 150. The second conductor 150, like the first conductors 120, may include a metal material having excellent electrical conductivity. A bit line may be electrically connected to the second conductor 150.

The second diffusion barrier layer 132 may be arranged between the chalcogenide layer 140 and the second conductor 150. The second diffusion barrier layer 132 may be formed in a cylindrical shape surrounding the second conductor 150. The second diffusion barrier layer 132 may be arranged to extend perpendicular to the substrate 101.

The second diffusion barrier layer 132, like the first diffusion barrier layers 131 described above, may limit and/or prevent the mixing between the metal material of the second conductor 150 and the chalcogenide material of the chalcogenide layer 140. The second diffusion barrier layer 132 may include a carbon-based material.

In the memory device 100 according to the present embodiment, as the first and second diffusion barrier layers 131 and 132 each including a carbon-based material are arranged between the chalcogenide layer 140 and the first and second conductors 120 and 150, the mixing between the metal material and the chalcogenide material may be limited and/or prevented, and accordingly, the characteristics of the memory device 100 may be improved. Furthermore, as the first diffusion barrier layers 131 are selectively arranged only on the first conductors 120, the generation of crosstalk between the memory cells MC may be limited and/or prevented. Due to a vertical memory structure in which the memory cells MC are vertically stacked on the substrate 101, the high integration of the memory device 100 may be implemented.

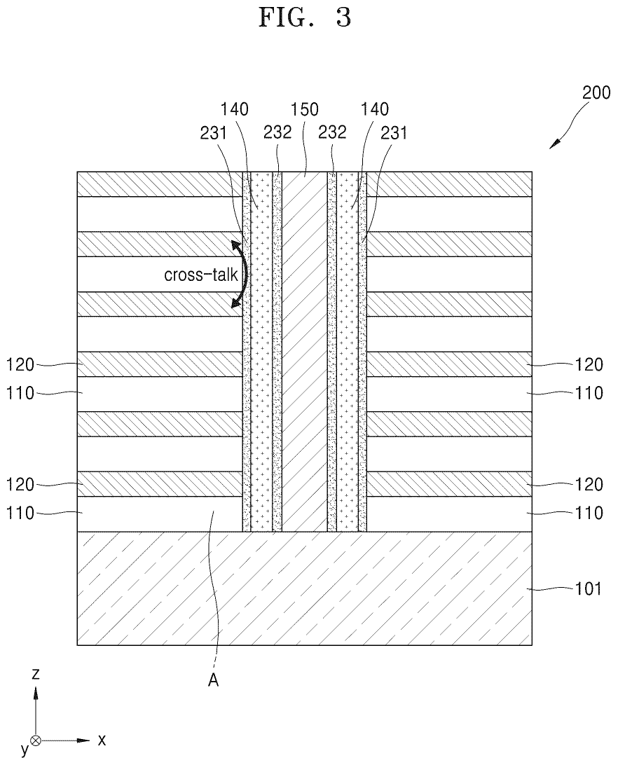

FIG. 3 is a cross-sectional view of a memory device 200 according to a comparative example. The memory device 200 illustrated in FIG. 3 is similar to the memory device 100 illustrated in FIG. 1, except for a first diffusion barrier layer 231 arranged between the first conductors 120 and the chalcogenide layer 140. In the following description, only differences from the memory device 100 illustrated in FIG. 1 are mainly described.

Referring to FIG. 3, the first diffusion barrier layer 231 is arranged between the first conductors 120 and the chalcogenide layer 140. A through-hole is formed in the first conductors 120 and the insulating layers 110 in a direction perpendicular to the substrate 101, and the first diffusion barrier layer 231 is arranged on the side surfaces of the first conductors 120 and the side surface of the insulating layers 110 exposed through the through-hole. The first diffusion barrier layer 231 is arranged to extend perpendicular to the substrate 101.

The first diffusion barrier layer 231 may limit and/or prevent the mixing between the metal material of the first conductors 120 and the chalcogenide material of the chalcogenide layer 140. The first diffusion barrier layer 231 may include a carbon-based material. A second diffusion barrier layer 232 is arranged between the chalcogenide layer 140 and the second conductor 150. The second diffusion barrier layer 232 may be arranged to extend perpendicular to the substrate 101. The second diffusion barrier layer 232, like the first diffusion barrier layer 231, may limit and/or prevent the mixing between the metal material of the second conductor 150 and the chalcogenide material of the chalcogenide layer 140. The second diffusion barrier layer 132 may include a carbon-based material.

In the memory device 200 illustrated in FIG. 3, the first conductors 120 may be connected to each other through the first diffusion barrier layer 231. In other words, as the carbon-based material forming the first diffusion barrier layer 231 has very high electrical conductivity, the first conductors 120 may be electrically connected to each other through the first diffusion barrier layer 231. Accordingly, crosstalk may be generated between the memory cells MC adjacent to each other, and the characteristics of the memory device 200 may deteriorate.

In contrast, in the memory device 100 according to an embodiment of FIG. 1, as the first diffusion barrier layers 131 are selectively arranged only on the first conductors 120 between the first conductors 120 and the chalcogenide layer 140, the first conductors 120 may be electrically separated from each other, and accordingly, the generation of crosstalk between the memory cells MC may be limited and/or prevented.

FIGS. 4A to 4D are views for explaining a method of manufacturing a memory device 100, according to an embodiment.

Referring to FIG. 4A, the insulating layers 110 and the first conductors 120 are alternately stacked in the direction (z-axis direction) perpendicular to the substrate 101. The substrate 101 may include various materials. For example, the substrate 101 may include a semiconductor material, such as Si, germanium (Ge), silicon germanium (SiGe), silicon carbide (SiC), gallium arsenic (GaAs), indium arsenic (InAs), indium phosphide (InP), and the like, and an insulating material, such as a silicon oxide, a silicon nitride, a silicon oxynitride, or the like. The substrate 101 may further include a driving circuit area. The driving circuit area may include one or more transistors and a wiring structure electrically connected to the transistors.

The first conductors 120 may each extend parallel to the substrate 101, and the insulating layers 110 may each extend parallel to the substrate 101. The first conductors 120 may each include a metal material having excellent electrical conductivity. For example, the first conductors 120 may each include TiN, Au, or the like, but the disclosure is not limited thereto. The insulating layers 110 may each include, for example, a silicon oxide, a silicon nitride, and the like. However, the disclosure is not limited thereto.

Next, the through-hole H is formed by etching the first conductors 120 and the insulating layers 110 so that the substrate 101 is exposed. The through-hole H may be formed to extend in the direction (z-axis direction) perpendicular to the substrate 101. The through-hole H may be formed to have, for example, a circular cross-section. The upper surface of the substrate 101 may be exposed through the bottom of the through-hole H, and the side surfaces of the first conductors 120 and the side surface of the insulating layers 110 may be exposed through the side wall of the through-hole H.

Referring to FIG. 4B, the first diffusion barrier layers 131 are selectively formed on the side surfaces of the first conductors 120 exposed through the through-hole H. Each of the first diffusion barrier layers 131 may be formed in a cylindrical shape. The first diffusion barrier layers 131 may each include a carbon-based material. For example, the first diffusion barrier layers 131 may each include a carbon layer. The first diffusion barrier layers 131 may each include a carbon nitride layer or a compound layer of carbon and chalcogenide.

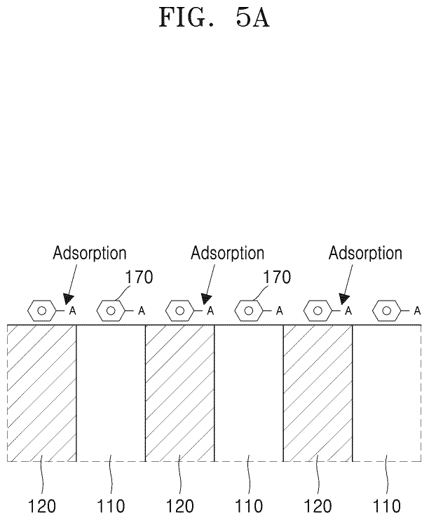

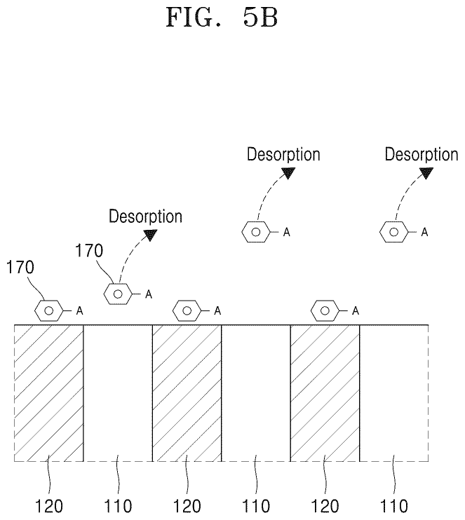

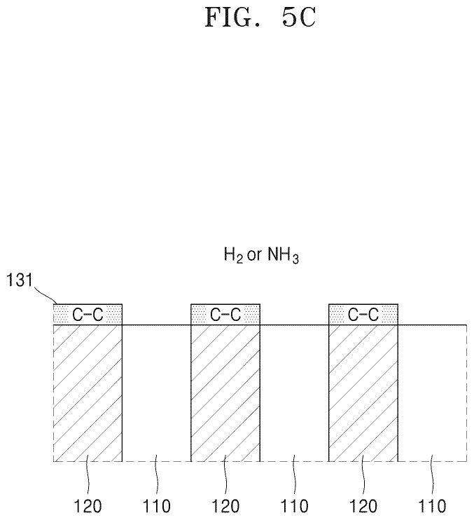

The first diffusion barrier layers 131 may be selectively formed only on the side surfaces of the first conductors 120 through ASD. In the following description, a process of forming the first diffusion barrier layers 131 through ASD is described with reference to FIGS. 5A to 5C. The side surfaces of the first conductors 120 and the side surfaces of the insulating layers 110, which are illustrated in FIG. 4B as being exposed through the through-hole H, are illustrated in FIGS. 5A to 5C, for convenience, as the upper surfaces of the first conductors 120 and the upper surfaces of the insulating layers 110.

Referring to FIG. 5A, a precursor 170 including carbon in a vaporized gas state is injected into a chamber of a deposition device. The precursor 170 may include, for example, a benzene-based material. The precursor 170 may include a cyclopentadien-based material or an aniline-based material. However, this is a mere example, and additionally, the precursor 170 may include various materials.

When the precursor 170 including carbon is injected into the chamber, the precursor 170 may be selectively adsorbed only on the upper surfaces of the first conductors 120, not on the upper surfaces of the insulating layers 110. As the d-orbital of a metal material forming the first conductors 120 and the sp-hybrid orbital of the precursor 170 form a π bond, the precursor 170 may be adsorbed on the upper surfaces of the first conductors 120.

This selective adsorption may be implemented by the difference in bonding characteristics between the first conductors 120 and the insulating layers 110, in detail, the difference between the bonding energy of the metal material of the first conductors 120 and the precursor 170 and the bonding energy of the insulating material of the insulating layers 110 and the precursor 170. For example, when TiN is used as the metal material of the first conductors 120 and SiO₂ is used as the insulating material of the insulating layers 110, the bonding energy of a benzene-based material and TiN may be about 0.30 eV/atom, and the bonding energy of a benzene-based material and SiO₂ may be about 0.04 eV/atom. As such, it may be seen that the bonding energy of a benzene-based material and TiN is about 8 times greater than the bonding energy of a benzene-based material and SiO₂, and thus, by using the bonding energy difference, the precursor 170 including carbon may be selectively adsorbed only on the upper surface of first conductors 120 including a metal material.

Referring to FIG. 5B, when a purging process is performed by injecting a purging gas into the chamber, the precursors 170 on the upper surfaces of the insulating layers 110 may be desorbed from the insulating layers 110 and discharged to the outside. The precursors 170 adsorbed on the upper surfaces of the first conductors 120 remain on the first conductors 120.

Referring to FIG. 5C, by injecting a reactive agent (e.g., a H₂ gas, a NH₃ gas, etc.) into the chamber after the purging process is completed, the precursor 170 adsorbed on the first conductors 120 reacts with the reactive agent so that the first diffusion barrier layers 131 including a carbon-based material may be formed on the upper surfaces of the first conductors 120. Then, the reaction residue, the reactive agent, and the like remaining in the chamber are discharged to the outside through the purging process. Accordingly, the first diffusion barrier layers 131 may be selectively deposited only on the upper surfaces of the first conductors 120.

The first diffusion barrier layers 131 may be formed as a carbon layer. The first diffusion barrier layers 131 may be formed as a carbon nitride layer as carbon reacts with the reactive agent (e.g., a NH₃ gas). Furthermore, as described below, when a chalcogenide layer is formed to cover the first diffusion barrier layers 131, the first diffusion barrier layers 131 may be formed as a compound layer of carbon and chalcogenide.

Referring back to FIG. 4B, the first diffusion barrier layers 131 may be selectively formed, through ASD described above, only on the side surfaces of the first conductors 120 exposed through the through-hole H. The first diffusion barrier layers 131 may limit and/or prevent the mixing between the metal material of the first conductors 120 and the chalcogenide material of the chalcogenide layer 140.

Referring to FIG. 4C, the chalcogenide layer 140 is deposited on the inner wall of the through-hole H. The chalcogenide layer 140 may be formed to cover the first diffusion barrier layers 131. The chalcogenide layer 140 may be formed to have a cylindrical shape and extend in a direction perpendicular to the substrate 101.

The chalcogenide layer 140 may include a chalcogenide material exhibiting non-volatile memory characteristics. The chalcogenide layer 140 may include at least one of a chalcogen element, Ge, As, and Sb. The chalcogen element may include at least one of Se, Te, and S. For example, the chalcogenide layer may include a GeAsSe-based material, a GeSbTe-based material, a GeAsS-based material, a GeSbSe-based material, a GeAsTe-based material, or a GeSbS-based material. The chalcogenide layer 140 may include a material (e.g., a GeAsSe-based material) having threshold switching characteristics. The chalcogenide layer 140 may include a material (e.g., GeSbTe) having phase change characteristics. In this case, the chalcogenide layer 140 may have a material (e.g., a GeAsSe-based material) having OTS characteristics.

Referring to FIG. 4D, the second diffusion barrier layer 132 and the second conductor 150 are formed on the chalcogenide layer 140. The second diffusion barrier layer 132 may be formed in a cylindrical shape surrounding the second conductor 150. The second diffusion barrier layer 132 may be arranged to extend perpendicular to the substrate 101. The second diffusion barrier layer 132 may limit and/or prevent the mixing between the metal material of the second conductor 150 and the chalcogenide material of the chalcogenide layer 140. The second diffusion barrier layer 132 may include a carbon-based material.

The second conductor 150 may be formed to fill the through-hole H formed inside the chalcogenide layer 140. The second conductor 150 may be arranged to extend perpendicular to the substrate 101. The second conductor 150 may be formed in a cylindrical shape, and in this case, a filling insulating layer (not shown) may be arranged in the through-hole H inside the second conductor 150. The second conductor 150, like the first conductors 120, may include a metal material having excellent electrical conductivity.

FIGS. 4E to 4I are views for explaining a method of manufacturing a memory device according to an embodiment. For brevity, differences between the embodiments in FIGS. 4A to 4D and 4E to 4I will be mainly described.

Referring to FIG. 4E, the insulating layers 110 and first conductors 120 may be alternately stacked in the direction (z-axis direction) perpendicular to the substrate 101. Next, a first through-hole H1 may be formed by etching through a portion of the insulating layers 110 and first conductors 120 so that the substrate 101 is exposed.

Referring to FIG. 4F, a preliminary second conductor layer 150′ may be formed by filling the first through through-hole H1 with a metal material (e.g., TiN, Au, or the like).

Referring to FIG. 4G, an outer portion the preliminary second conductor layer 150′ may be etched to form the second conductor layer 150 and a second through-hole H2 between the second conductor layer 150 and the insulating layer 110 and first conductors 120 alternately stacked. Although not illustrated, a mask may be provided over the insulating layers 110, first conductors 120, and a central region of the preliminary second conductor layer 150′. The mask may expose regions of the preliminary second conductor layer 150′ corresponding to the second through-hole H2 and the exposed regions of the preliminary second conductor layer 150′ may be etched through the mask to form the second through-hole H2.

Referring to FIG. 4H, using an ASD process, the first diffusion barrier layers 131 may be selectively formed on only on exposed sidewalls of the first conductors 120 and the second diffusion barrier layer 132 may be formed on a sidewall of the second conductor layer 150.

Referring to FIG. 4I, the chalcogenide layer 140 may be formed in a remaining portion of the second through-hole H2. The chalcogenide layer 140 may extend in the direction (2-axis direction) perpendicular to the substrate 101. The chalcogenide layer 140 may be arranged between the first diffusion barrier layers 131 and the second diffusion barrier layer 132 and the chalcogenide layer 140 may be arranged between the plurality of insulating layers 110 and the second diffusion barrier layer 132.

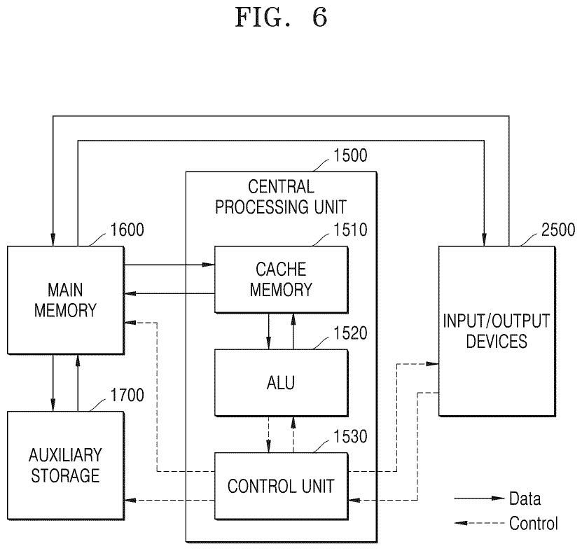

The memory device 100 according to the embodiment described above may be used for data storage in various electronic apparatuses. FIG. 6 is a conceptual block diagram schematically showing an example of a device architecture applicable to an electronic apparatus, according to an embodiment.

Referring to FIG. 6, a cache memory 1510, an arithmetic logic unit (ALU) 1520, and a control unit 1530 constitute a central processing unit (CPU) 1500, and the cache memory 1510 may include static random access memory (SRAM).) Aside from the CPU 1500, a main memory 1600 and an auxiliary storage 1700 may be provided. The main memory 1600 may include a DRAM device, and the auxiliary storage 1700 may include the memory device 100 (a vertical non-volatile memory device) described above. In some embodiments, input/output devices 2500 may also be disposed. In some cases, the device architecture may be implemented in the form of computing unit devices and memory unit devices that are adjacent to each other in one chip without distinction of sub-units.

The memory device 100 according to the embodiment described above may be implemented as a memory block in the form of a chip and used as a neuromorphic computing platform, or used for constituting a neural network.

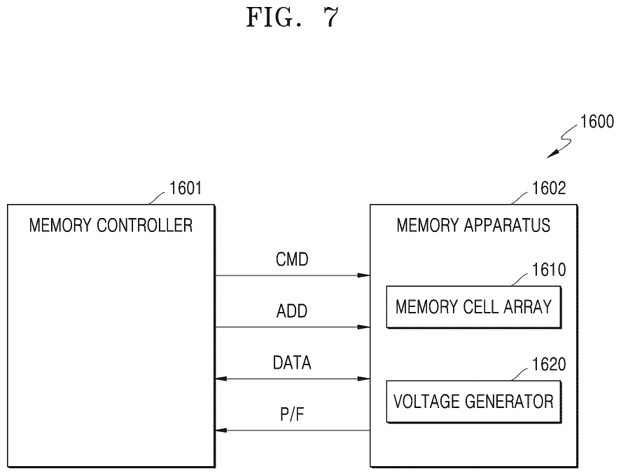

FIG. 7 is a block diagram of a memory system 1600 according to an embodiment.

Referring to FIG. 7, the memory system 1600 may include a memory controller 1601 and a memory apparatus 1602. The memory controller 1601 performs a control operation on the memory apparatus 1602. For example, the memory controller 1601 provides the memory apparatus 1602 with an address ADD and a command CMD to perform a programming (or recording) operation or a read and/or erase operation on the memory apparatus 1602. Furthermore, data for the programming operation and read data may be transmitted between the memory controller 1601 and the memory apparatus 1602.

The memory apparatus 1602 may include a memory cell array 1610 and a voltage generator 1620. The memory cell array 1610 may include a plurality of memory cells, and include the memory device 100 (a vertical non-volatile memory device) according to the embodiment described above.

The memory controller 1601 may include processing circuitry such as hardware including a logic circuit, a hardware/software combination such as processor-executable software, or a combination thereof. For example, the processing circuitry may include, in detail, a CPU, an ALU, a digital signal processor, a microcomputer, a field programmable gate array (FPGA), a system-on-chip (SoC), a programmable logic unit, a microprocessor, an application-specific integrated circuit (ASIC), and the like, but the disclosure is not limited thereto. The memory controller 1601 may operate in response to a request from a host (not shown), access the memory apparatus 1602, and control the control operation (e.g., record/read operation) discussed above, and thus, the memory controller 1601 may be configured to be converted into a special purpose controller. The memory controller 1601 may generate the address ADD and the command CMD to perform a programming/read/erase operation on the memory cell array 1610. Furthermore, in response to a command from the memory controller 1601, the voltage generator 1620 (e.g., a power circuit) may generate a voltage control signal to control the voltage level of a word line for data programming or data read on the memory cell array 1610.

Furthermore, the memory controller 1601 may perform a determination operation on the data read from the memory apparatus 1602. For example, on-cell number and/or off-cell number may be determined from the data read from a memory cell. The memory apparatus 1602 may provide a pass/fail signal P/F to the memory controller 1601 based on a read result of the read data. The memory controller 1601 may control a write and read operation on the memory cell array 1610 with reference to the pass/fail signal P/F.

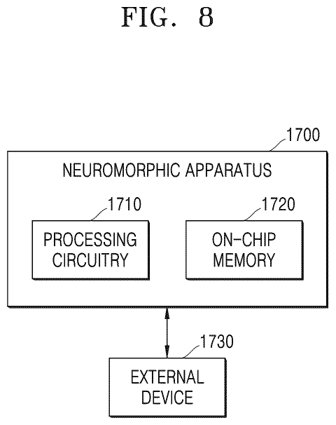

FIG. 8 is a block diagram of a neuromorphic apparatus 1700 according to an embodiment and an external device connected thereto.

Referring to FIG. 8, the neuromorphic apparatus 1700 may include processing circuitry 1710 and/or an on-chip memory 1720. The neuromorphic apparatus 1700 may include the memory device 100 according to an embodiment described above (a vertical non-volatile memory device).

In some embodiments, the processing circuitry 1710 may be configured to function to drive the neuromorphic apparatus 1700. For example, the processing circuitry 1710 may be configured to control the neuromorphic apparatus 1700 by executing a program stored in the on-chip memory 1720. In some embodiments, the processing circuitry 1710 may include hardware such as a logic circuit, a hardware/software combination such as a processor for executing software, or a combination thereof. For example, the processor may include a CPU, a graphics processing unit (GPU), an application processor (AP) included in the neuromorphic apparatus 1700, an ALU, a digital signal processor, a microcomputer, an FPGA, an SoC, a programmable logic unit, a microprocessor, an ASIC, and the like, but the disclosure is not limited thereto. In some embodiments, the processing circuitry 1710 may be configured to read/record various pieces of data with respect to an external device 1730, and/or execute the neuromorphic apparatus 1700 by using the read/recorded data. In some embodiments, the external device 1730 may include a sensor array and/or an external memory having an image sensor (e.g., a CMOS image sensor circuit).

In some embodiments, the neuromorphic apparatus 1700 of FIG. 8 may be applied to a machine learning system. The machine learning system may use various artificial neural network systems and processing models, such as a convolution neural network (CNN), a deconvolution neural network, a recurrent neural network (RNN) selectively including a long short-term memory (LSTM) unit, and/or a gated recurrent unit (GRU), a stacked neural network (SNN), a state-space dynamic neural network (SSDNN), a deep belief network (DBN), a generative adversarial network (GAN), and/or a restricted Boltzmann machine (RBM).

Alternatively or additionally, this machine learning system may include different types of machine learning models, for example, linear and/or logistic regression, statistical clustering, Bayesian classification, decision trees, dimensionality reduction such as principal component analysis, expert system, and/or a combination thereof including an ensemble such as random forests. These machine learning models may be used to provide a variety of services and/or applications, and for example, image classification services, user authentication services based on biometric information or biometric data, advanced driver assistance system (ADAS) services, voice assistant services, automatic speech recognition (ASR) services, and the like may be executed by electronic devices.

In the memory device according to an embodiment, as the first and second diffusion barrier layers each including a carbon-based material are arranged between the chalcogenide layer and the first and second conductors, the mixing between the metal material and the chalcogenide material may be limited and/or prevented, and thus, the memory device characteristics may be improved. Furthermore, as the first diffusion barrier layers are selectively arranged only on the first conductors between the first conductors and the chalcogenide layer, the generation of crosstalk between the memory cells may be limited and/or prevented. Due to the vertical memory structure in which the memory cells MC are vertically stacked on the substrate 101, the high integration of the memory device 100 may be implemented. While the memory device 100 described above has been particularly shown and described with reference to embodiments using specific terminologies, the embodiments and terminologies should be considered in descriptive sense only and not for purposes of limitation. Therefore, it will be understood by those of ordinary skill in the art that various changes in form and details may be made therein without departing from the spirit and scope of the disclosure as defined by the following claims.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A memory device comprising:
a plurality of first conductors arranged apart from each other and perpendicular to a substrate;
a second conductor extending perpendicular to the substrate;
a chalcogenide layer extending perpendicular to the substrate between the plurality of first conductors and the second conductor; and
a plurality of first diffusion barrier layers selectively arranged only on the plurality of first conductors between the plurality of first conductors and the chalcogenide layer, the plurality of first diffusion barrier layers each including a carbon-based material.

2. The memory device of claim 1, wherein
each of the plurality of first conductors extends parallel to the substrate, and
the plurality of first diffusion barrier layers are on side surfaces of the plurality of first conductors.

3. The memory device of claim 1, wherein each of the plurality of first diffusion barrier layers includes carbon, a carbon nitride, or a compound of carbon and chalcogenide.

4. The memory device of claim 1, wherein the plurality of first conductors and the second conductor each include a metal material.

5. The memory device of claim 1, wherein the chalcogenide layer includes at least one of a chalcogen element, Ge, As, and Sb.

6. The memory device of claim 5, wherein the chalcogenide layer includes a GeAsSe-based material, a GeSbTe-based material, a GeAsS-based material, a GeSbSe-based material, a GeAsTe-based material, or a GeSbS-based material.

7. The memory device of claim 1, further comprising:
a second diffusion barrier layer between the chalcogenide layer and the second conductor, wherein
the second diffusion barrier layer includes a carbon-based material.

8. The memory device of claim 7, wherein the second diffusion barrier layer extends perpendicular to the substrate.

9. The memory device of claim 1, further comprising:
a plurality of insulating layers between the plurality of first conductors.

10. An electronic apparatus comprising:
the memory device set forth in claim 1.

11. A method of manufacturing a memory device, the method comprising:
alternately stacking a plurality of first conductors and a plurality of insulating layers above a substrate;
forming a through-hole penetrating the plurality of first conductors and the plurality of interlayer insulating layers in a direction perpendicular to the substrate;
selectively depositing a plurality of first diffusion barrier layers only on side surfaces of the plurality of first conductors exposed through the through-hole, the plurality of first diffusion barrier layers each including a carbon-based material;
forming a chalcogenide layer on an inner wall of the through-hole; and
forming a second conductor on the chalcogenide layer.

12. The method of claim 11, wherein each the plurality of first diffusion barrier layers includes carbon, a carbon nitride, or a compound of carbon and chalcogenide.

13. The method of claim 11, wherein the plurality of first conductors and the second conductor each include a metal material.

14. The method of claim 11, wherein the chalcogenide layer includes at least one of a chalcogen element, Ge, As, and Sb.

15. The method of claim 14, wherein the chalcogenide layer includes a GeAsSe-based material, a GeSbTe-based material, a GeAsS-based material, a GeSbSe-based material, a GeAsTe-based material, or a GeSbS-based material.

16. The method of claim 11, wherein the selectively depositing the plurality of first diffusion barrier layers comprises:
selectively adsorbing a precursor including carbon only on the side surfaces of the plurality of first conductors; and
forming the plurality of first diffusion barrier layers by reacting the precursor adsorbed on the side surfaces of the plurality of first conductors with a reactive agent.

17. The method of claim 16, wherein the precursor includes a benzene-based material, a cyclopentadien-based material, or an aniline-based material.

18. The method of claim 11, wherein the chalcogenide layer and the second conductor each are formed to extend perpendicular to the substrate.

19. The method of claim 18, further comprising:
forming a second diffusion barrier layer including a carbon-based material between the chalcogenide layer and the second conductor.

20. The method of claim 19, wherein the second diffusion barrier layer extends perpendicular to the substrate.
